(19) United States
(12) Patent Application Publication
(10) Pub. No.: US 2024/0070356 A1
(43) Pub. Date: Feb. 29, 2024

(54) METHODS AND DEVICES FOR STENCIL-BASED PORE NETWORK CONSTRUCTION

(71) Applicant: UNIVERSITY OF WYOMING, Laramie, WY (US)

(72) Inventors: Bradley MCCASKILL, Laramie, WY (US); Mohammad PIRI, Laramie, WY (US)

(21) Appl. No.: 18/239,518

(22) Filed: Aug. 29, 2023

Related U.S. Application Data
(60) Provisional application No. 63/401,994, filed on Aug. 29, 2022.

(51) Int. Cl. G06F 30/28

(52) U.S. Cl. CPC G06F 30/28

(57) ABSTRACT

A method for pore network construction by one or more processors is disclosed. The method may include generating one or more sample pore bodies based on a representative pore network corresponding to a porous media sample, selecting a target pore body from the one or more sample pore bodies, adding the target pore body to a generated pore network, the generated pore network associated with one or more target parameters, replicating one or more pore throat connections from the representative pore network substantially within the generated pore network, the one or more pore throat connections disposed between the target pore body and one or more duplicated neighbors of the target pore body, and processing the generated pore network to substantially align the generated pore network with the representative pore network.

### CROSS-REFERENCE TO RELATED APPLICATIONS

This applications claims benefit of U.S. Provisional Patent Application No. 63/401,994, filed Aug. 29, 2022, the entirety of which is herein incorporated by reference.

### BACKGROUND

### Field

Aspects of the present disclosure generally relate to characterizing of porous media, and more particularly to techniques for constructing a pore network based on a porous media sample.

### Description of the Related Art

Modeling techniques for fluid flow through porous media are broadly implemented for petroleum resource development, materials engineering, food packaging, and medical technology development. Fluid flow modeling techniques may be equipped to illustrate both physical and chemical media properties like permeability, capillary pressure, fluid saturation, contact angle, wettability, or other similar properties, which may be used to characterize fluid behavior.

Although current techniques for modelling fluid flow through porous media are based on technological advancements made over many years, resultant models may still be tenuous representations of actual porous media. For example, fluid flow models of porous media exceeding a few millimeters may require a lower resolution implementation to match currently available computational capabilities. As a result, fluid flow models based on porous media of a larger scale may not accurately reflect physical and chemical properties of the media. Accordingly, there is an impetus to improve the accuracy of fluid flow modeling, including, for example: improving image processing techniques to allow for higher resolution model input and model output, improving image processing techniques to allow for more accurate model input and model output, enhancing computational processing capability to reduce computational expense, enhancing computational processing capability increase modeling speed, increasing automation for iterative modeling steps, improving model capability for dynamic modeling of different fluid flow environments, improving model capability for dynamic modeling of larger fluid flow environments, and the like.

Consequently, there exists a need for further improvements in fluid flow modeling of porous media to overcome the aforementioned technical challenges and other challenges not mentioned.

### SUMMARY

One aspect of the present disclosure provides a method for pore network construction by one or more central processing units (CPU). The method may include generating one or more sample pore bodies based on a representative pore network corresponding to a porous media sample. The method may include selecting a target pore body from the one or more sample pore bodies. The method may include adding the target pore body to a generated pore network, the generated pore network associated with one or more target parameters. The method may include replicating one or more pore throat connections from the representative pore network substantially within the generated pore network, the one or more pore throat connections disposed between the target pore body and one or more duplicated neighbors of the target pore body. The method may include processing the generated pore network to substantially align the generated pore network with the representative pore network.

One aspect of the present disclosure provides an apparatus for porous media characterization comprising a memory and one or more CPU, the one or more CPUs configured to cause the apparatus to perform a method. The method may include selecting a target pore body from the one or more sample pore bodies. The method may include adding the target pore body to a generated pore network, the generated pore network associated with one or more target parameters. The method may include replicating one or more pore throat connections from the representative pore network substantially within the generated pore network, the one or more pore throat connections disposed between the target pore body and one or more duplicated neighbors of the target pore body. The method may include processing the generated pore network to substantially align the generated pore network with the representative pore network.

Other aspects provide: an apparatus operable, configured, or otherwise adapted to perform the aforementioned methods as well as those described elsewhere herein; a non-transitory, computer-readable media comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and an apparatus comprising means for performing the aforementioned methods as well as those described elsewhere herein. By way of example, an apparatus may comprise a processing system, a device with a processing system, or processing systems cooperating over one or more message passing interfaces.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only example aspects and are therefore not to be considered limiting of its scope, may admit to other equally effective aspects.

FIG. 1A depicts an example ball and stick representation of a pore network model extracted from a porous media sample made of sandstone.

FIG. 1B depicts an example two-dimensional (2D) slice of a set of high-resolution porous media image taken by a scanning instrument from a single rock sample and segmented for characterization, and a ball and stick representation of a pore network extracted from them.

FIG. 2 depicts an example core-flooding instrument for determining the physical and chemical characteristics of a porous media sample.

FIG. 3 depicts an example pore network construction procedure for characterizing of porous media by one or more central processing units (CPU).

FIG. 4 depicts example stencils, generated according to aspects of the present disclosure.

FIG. 5 depicts example stencils placed to define the generated pore network (left) and the finalized pore network obtained after stitching these stencils together using one or more CPUs using stochastic stencil duplication.

FIG. 6 depicts an example representative pore network and a corresponding pore network constructed by one or more CPUs using stochastic stencil duplication.

FIG. 7 illustrates example predicted relative permeability curves for primary drainage and imbibition obtained using quasi-static pore network modeling simulations on a representative pore network and five realizations of constructed pore networks.

FIG. 8 depicts a stochastically generated digital plug composed of approximately 220 million pore elements.

FIG. 9 is a flow diagram illustrating certain operations by one or more CPUs, according to certain aspects of the present disclosure.

FIG. 10 is an example device for extracting pore networks.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

In the following, reference is made to aspects of the disclosure. However, it should be understood that the disclosure is not limited to specifically described aspects. Instead, any combination of the following features and elements, whether related to different aspects or not, is contemplated to implement and practice the disclosure. Furthermore, although aspects of the disclosure may achieve advantages over other possible solutions and/or over the prior art, whether or not a particular advantage is achieved by a given aspect is not limiting of the disclosure. Thus, the following aspects, features, embodiments, and advantages are merely illustrative and are not considered elements or limitations of the appended claims except where explicitly recited in a claim(s). Likewise, a reference to “the disclosure” shall not be construed as a generalization of any inventive subject matter disclosed herein and shall not be considered to be an element or limitation of the appended claims except where explicitly recited in a claim(s).

The present disclosure relates to techniques for physical characterization of porous media. Specifically, the techniques discussed herein may be implemented for non-destructive extraction of geometry information, capillary pressure and wettability information from porous media samples. The porous media sample may comprise a digital rock sample, a rock sample, a core sample, a plastic sample, a tissue sample, a rough-walled fracture space, or any other organic or inorganic sample having pore space ascertainable through imaging techniques.

A thorough grasp of fluid flow through porous spaces of certain materials may be consequential to enhancing technical efficacy of fluid flow techniques in a wide range of industries. Models of fluid flow are useful to describe physical and chemical characteristics of a porous material and may help to highlight the material's optimal usage. Often, networks of pores within a material are extremely small (e.g., microscale in size). Techniques for characterizing these pore networks are hindered by the computational expense of modeling at a microscale. To alleviate computational burdens, pore network modelling techniques often implement generalized characterization techniques at expense of model accuracy. Extrapolation errors caused by such imprecise characterization may result in mischaracterization of physical and chemical characteristics of the porous material. In many cases, these errors render such models impractical for regular use. Accordingly, ideal modeling of fluid flow through porous media would allow for rapid, accurate characterization of microscale pore spaces that may be performed without inhibitive computational expense.

Implementation of techniques for efficiently generating high-resolution pore networks as described herein may enhance pore network modelling functionality by reducing porous material characterization errors to the benefit of all users seeking a more comprehensive understanding of any given porous material.

### Introduction to Pore Network Modeling

Modeling techniques for fluid flow through porous media may illustrate both physical and chemical porous media properties. Models of porous media may be used to ascertain permeability, capillary pressure, fluid saturation, wettability, buoyancy, and the like to a greater degree of accuracy more comparable to physical flooding of a porous media sample. Additionally, physical and chemical properties determined using pore network modeling techniques may be used to characterize in-situ fluid behavior as it travels through the porous media under a wide variety of wettability and flooding conditions. These conditions are not typically accessible to users performing conventional physical flooding characterization techniques.

Permeability is the tendency of the porous media to allow liquids to flow through the porous media. Capillary pressure is the pressure difference existing across the interface separating two immiscible fluids. Fluid saturation is the measurement of fluid present in the pore spaces of the porous media. Contact angle is a measured angle between a fluid-fluid or a fluid-gas interface at a point where it meets a solid surface. Wettability is the ability of a liquid to maintain contact with a solid surface. Wettability may vary depending on wettability conditions and the type of wetting liquid present in the porous media sample. For example, a water-wet medium may show a lower wetting affinity to the oil phase than an oil-wet medium, where higher or lower wetting is determined with respect to a given phase. In certain cases, the correlation between wettability and viscosity ratio may not be straightforward, as there may be water or oil wet conditions with similar viscosities.

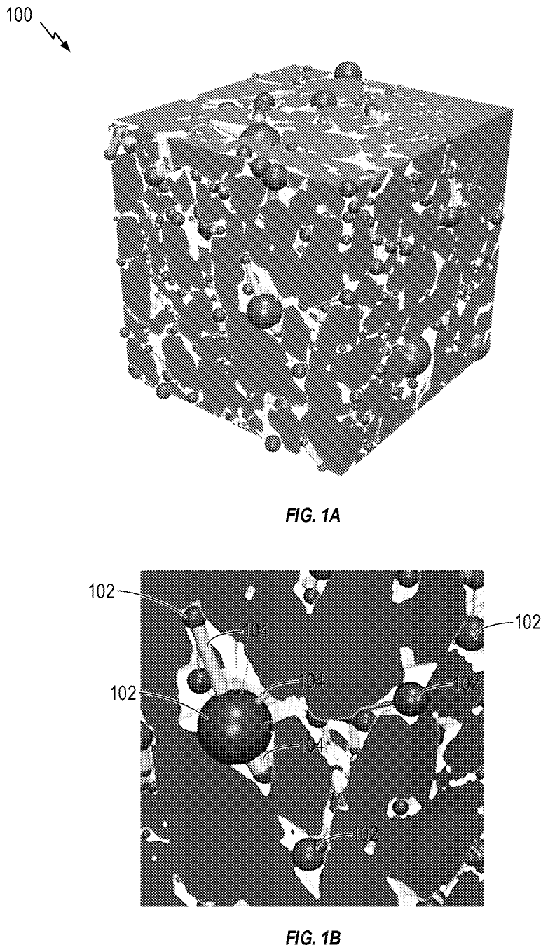

A modeled pore network is a practical description of a porous medium targeted for fluid flow modeling. FIG. 1A illustrates an example of a pore network section extracted from porous sandstone. The example section of the pore network describes the porosities of various size and shape present in that portion of the sandstone, and may be used to model fluid flow through those porosities for various wettability conditions. Three-dimensional (3D) portions of a pore network model may more accurately characterize the porous media sample either alone or in combination with other 3D portions of the pore network model.

Pore network models (e.g., of FIG. 1A) may be extracted from images of a targeted porous medium and used to model multi-phase fluid flow using physically-based displacement mechanisms (PBDMs) across pores defined in a pore network. PBDMs may represent an estimated displacement of a modeled fluid in response to movement of another fluid or gas within the pore network. As immiscible phases react with one another throughout the pore network during fluid flooding, PBDMs are induced where, for example, capillary pressure across a meniscus exceeds the wettability constraints on either phase. Fluid saturation, contact angle, buoyancy, and the like may also affect PBDMs throughout a pore network. By utilizing a pore network model extracted from a porous media sample, a user is able to ascertain PBDMs through the porous media sample under a wide variety of wettability conditions in order to ultimately obtain, for example, useful permeabilities for a larger sample of the porous medium without degrading a porous media sample via repeated physical flooding.

To properly generate PBDMs at a pore scale for the targeted porous media, imaging may capture complex geometries of the targeted porous media at a resolution sufficiently high to retain acceptable accuracy. An example of these geometries is illustrated in FIG. 1B. Pores may be defined as a complex polyhedron having at least a center 102 and spherical and effective diameters. Connective throats 104 between pores may also be defined. In many cases, image resolution may be in micrometers to capture applicable pore detail. High-resolution pore models enable accurate rendering of the fluid flow characteristics described above as ascertained at each pore and for each PBDM.

PBDMs may occur upon flooding or draining of a pore network model, where aqueous phase injection or removal is iteratively simulated through the pore network. Aqueous flooding and aqueous draining may be implemented in various modeled wettability conditions, where certain fluids are present prior to the start of a simulation. Wettability conditions may include at least water-wet, oil-wet, or mixed-wet conditions. During aqueous flooding, injected water may displace immiscible fluid preexisting in the pore network model. During aqueous draining, injected immiscible fluid may displace water preexisting in the pore network model. In certain cases, flooding and draining may be fluid flooding and fluid draining. In some cases, the fluid is oil.

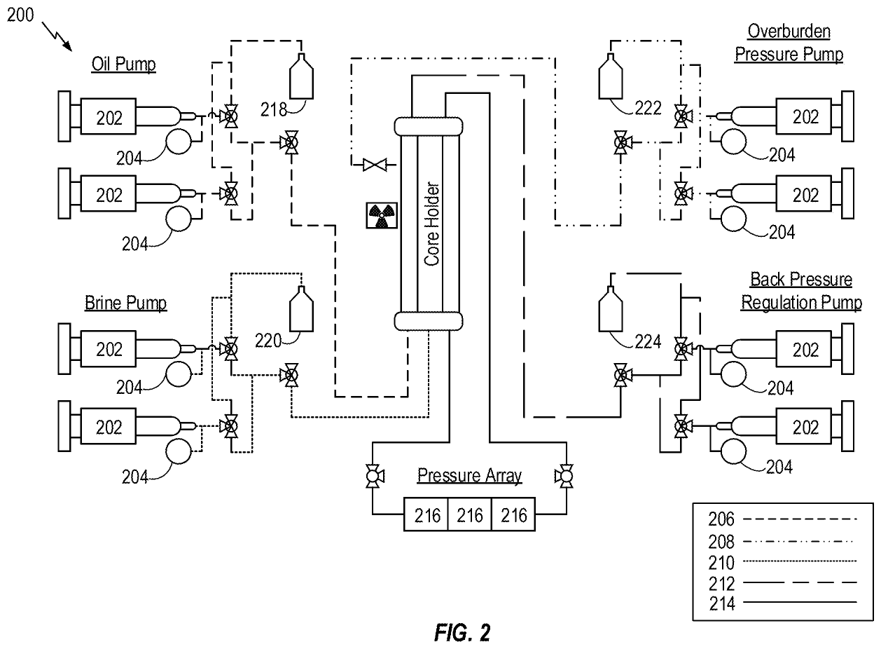

Flooding or draining of a pore network model may be simulated based in part on scanned images of physical flooding implemented by a flooding instrument 200 of FIG. 2. In some cases, a porous media may undergo a core-flooding experiment to establish an irreducible water saturation, a residual oil saturation, or both. Core-flooding is enabled by a set of pumps 202, rupture disks 204, pump lines 206-214, differential pressure transducers 216, and source buckets 218-222 working in tandem to flood a porous media sample loaded in a core holder. In some cases, a scanning instrument (e.g., a micro computed tomography (micro-CT) scanner) captures a dry reference image prior to flooding. Scanning occurs in a field of view defined within the core holder. The porous media sample may be flooded with brine from bucket 220 via the brine tubing line 206 and scanned again to ensure that the porous media sample is fully saturated. Once the brine flooding is complete, the absolute permeability of the porous media sample may be obtained. The oil flooding may be performed alongside additional brine flooding. Any fluid expelled as a result of overburden pressure (i.e., pressure that compacts pore space and reduces permeability) is transported via the confining fluid line 208 and collected in bucket 222. Any fluid expelled as a result of the flooding procedure is transported via the effluent fluid line 212 and collected in bucket 224. In many cases, core sample pressure may be iteratively adjusted during flooding. Pressure may be recorded by one or more differential pressure transducers 216 coupled to the core holder via a transducer line 214.

Scanned images obtained from flooding procedures performed by the flooding instrument 200 of FIG. 2 may be used to extract a pore map representative of the porous media sample prior to, during, or after flooding. The images may be processed to determine characteristics of fluid flow through the porous media sample. In many cases, the images may also be used to extract a representative pore network model.

Imaging of porous media is typically performed using micro-CT imaging. In many cases, commercial micro-CT scanners (e.g., Zeiss scanners) are available for imaging necessary to perform pore network modelling. Images of porous media taken by micro-CT scanners are at a sufficiently high resolution to create a microscale digital image of the porous media.

In the current state of the art, there exists a challenge of extracting porous media characteristics in a manner precise and repeatable to ensure the ultimate stability of future simulations. Currently, techniques for porous media characterization require lengthy step-wise processing known to incur undue computational expense and introduce instability to characterization of the porous media sample. As a result, users may not be able to rely on characterization output to simulate flow conditions in a useful way.

### Aspects Related to Pore Network Construction

Fluid flow modelling through porous media is often utilized to enhance petroleum resource development. In recent years, global demand for energy resources has mobilized development of unconventional petroleum reservoirs as targets for hydrocarbon extraction. Geological formations that comprise these newly developed hydrocarbon reservoirs are ultra-tight shale formations resistant to primary petroleum extraction techniques. A matrix of an ultra-tight unconventional shale reservoir may be characterized by low permeability and low porosity. To extract hydrocarbons from the ultra-tight shale matrix, secondary and tertiary petroleum extraction techniques seek to maximize oil production through the microscale pore networks that comprise a substantial amount of the porosity in the shale matrix.

A robust understanding of fluid flow through microscale pore networks of hydrocarbon reservoirs may be consequential to extracting the trillions of barrels of oil and gas still housed in shale formations globally. Models of fluid flow through a pore network that incorporates permeability, capillary pressure, fluid saturation, contact angle, wettability may help to elucidate specific steps to be taken during resource development to optimize petroleum production. Even so, techniques for characterizing these microscale pore networks are hindered by the computational expense of modeling microscale pore network and extrapolation errors caused by oversimplified characterization of pore geometries.

As discussed above, ideal modeling of fluid flow through porous media would allow for precise, quick, and repeatable characterization of a porous media sample. In a case where the porous media sample is, for example, a cylindrical core sample of a rock having a length of six inches and a diameter of one inch, the core sample is likely to have porosity and permeability characteristics that vary across its length and width. This is common in core samples and especially in core samples representative of ultra-tight oil formations. Geological processes that form certain oil-bearing rocks can produce heterogeneous morphological features in the rock that may be present even at a micrometer scale. This is especially true for oil-bearing carbonate rocks, which contain micro-porosities that contribute significantly to the overall porosity of the rock. These microscale morphological features may affect the pore network of the core sample, altering the porosity and permeability throughout a core sample. Thus, accurate characterization of fluid flow through a core sample may depend on precisely ascertained and verifiable microscale geometries sufficient to detect heterogeneous properties of a pore network. Using conventional estimation techniques that cannot consistently capture the heterogeneity and complexity of either the core sample or the fluid-fluid interfaces present therein may result in characterization of a porous media sample that cannot be used to consistently describe fluid flow through the core sample.

According to certain aspects of the present disclosure, to properly develop and test upscaling methods for pore network modeling, techniques for obtaining plug-sized pore networks (e.g., digital plugs) may be implemented. When imaging a pore space, there may be a trade-off between the imaging resolution and the size of the field of view. Since the images used for network construction must sufficiently resolve the microscale pore structure of porous media samples, the size of deterministically obtained networks is typically limited.

According to aspects of the present disclosure, the pore network construction procedure described herein may be performed by a processing system architecture comprising at least one or more central processing units (CPUs) operating independently or in combination with one or more graphics processing units (GPUs). Techniques for pore network construction performed by processors operating in sequence may be unable to support the computational load associated with microscale pore networks. Techniques implemented herein may address issues with resolution sufficiency and issues arising from the computational expense of high-resolution pore network construction. The one or more CPUs and/or the one or more GPUs may perform the procedures according to a non-transitory computer readable medium that causes the one or more CPUs and/or the one or more GPUs to perform any and all steps of the procedure. Each of the one or more CPUs may be utilized in combination with a memory having the computer readable medium stored thereon. Each of the one or more CPUs be utilized in combination with one or more processors. Each of the one or more processors may be parallel processors. Each of the one or more GPUs may be utilized in combination with a memory having the computer readable medium stored thereon. Each of the one or more GPUs be utilized in combination with one or more processors. Each of the one or more processors may be parallel processors. Each of the CPUs and the GPUs may operate independently, or may operate using a message passing interface (MPI) enabling communication between one or more parallel processors for performing the procedure. This may include CPU-CPU communication, CPU-GPU communication, and/or GPU-GPU communication.

Implementing aspects of the present disclosure provide a reliable way to generate unstructured networks of arbitrary sized and shapes that replicate the key properties of targeted porous media samples. Specifically, implementation of a stencil-based stochastic pore network generation technique may be used to create pore network models (e.g., digital plugs) that mimic the physical properties of conventionally-sized input networks. Notably, the techniques may be implemented by one or more parallel processors, and may efficiently generate pore network models using limited computational resources within a practical amount of time.

Aspects of the present disclosure provide techniques for emulating physical properties (e.g., petrophysical properties) captured by a representative pore network by replicating the support of its pore elements (e.g., pore body elements and/or pore throat elements), where the representative pore network may mimic certain physical structures of a porous media sample. Specifically, existing pore elements may be sampled from the input representative network and randomly placed within the desired dimensions of a subsequently generated pore network. Then, using the connectivity information of the representative pore elements, several layers of surrounding pore elements may be added to the generated pore network. In this way, the local topology of the input network may be preserved within the generated pore network, thus producing a useful generated pore network that preserves the physical characteristics of the initial porous media sample.

In certain cases, the placement of each pore body element and the replication of their support can be performed independently with limited communication between threads. After the generated pore network has an equivalent density of pore body elements as the input representative pore network, additional pore throat elements may be added to provide connections between replicated pore body elements. Placement of these pore throat elements is determined using the coordination numbers of the input representative network, and the geometrical information of the neighboring pore throat elements of each pore body elements.

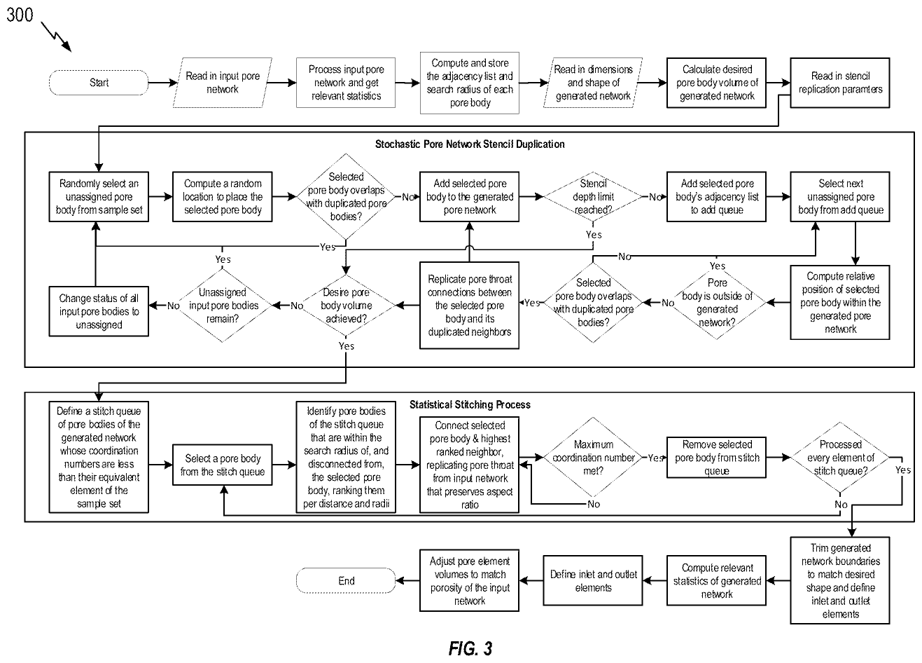

According to certain aspects, construction of a generated pore network may consist of four major steps performed by one or more processors: pre-processing, stochastic stencil duplication, statistical stitching, and post-processing. An example flow chart of the entire stencil-based pore network construction process 300 is provided in FIG. 3.

As illustrated in FIG. 3, the pre-processing step is performed to read in and process the representative pore network to define the sample set. First, the input representative pore network is read in by one or more processors (e.g., one or more CPUs) and processed to obtain relevant statistics. The processors read in user defined parameters such as the stencil-depth limit, and parameters related to defining pore element search radii. The processors compute and store adjacency lists and search radii for each representative pore body element. The processors read in the dimensions and shape of the generated pore network to be constructed during the procedure and read in a set of stencil replication parameters.

During the stochastic stencil duplication step illustrated in FIG. 3, the elements of a sample set are randomly distributed within the desired dimensions of the generated pore network. After a sample element is placed, a depth-limited breadth first search (BFS) is used to identify and replicate its stencil elements. To perform the stochastic stencil duplication step, the one or more processors randomly select an unassigned pore body element from a designed sample set of pore elements within the representative pore network. The processors then compute a random location within the defined dimensions and shape of generated pore network and place the selected pore body element in that position. The processor evaluates whether the placed pore body element overlaps with previously placed pore bodies. If there is overlap, the processors select a different pore body element from the sample set and begin the placement again. If there is no overlap, the processors add the selected pore body element to the generated pore network. The processors then evaluate whether a stencil-depth limit is reached. If the stencil-depth limit is reached, the processors evaluate whether a desired pore body volume has been achieved and either proceed on to the statistical stitching step, otherwise they select a different pore body element from the sample set and begin the placement process again. If the stencil-depth limit is not reached, the processors add the selected pore body element's adjacency list to an add queue. The processors then select the next unassigned pore body element from the add queue. The processors compute the relative position of the newly selected pore body element within the generated pore network. If the newly selected pore body element is outside of the generated pore network, a next unassigned pore body is reselected. If the newly selected pore body element is inside of the generated pore network, the processors evaluate whether the newly selected pore body element overlaps with duplicated pore body elements, either reselecting the newly selected pore body element, or proceeding to replication. The processors proceed to replication when the newly selected pore body element does not overlap with other duplicated pore body elements. During replication, the processors replicate the pore throat element connections between the selected pore body elements and its duplicated neighbors. The processors then evaluate whether a desired pore body volume has been achieved. If the desired pore body volume has not been achieved, the processors evaluate whether any unassigned input representative pore body elements remain and either: (1) select a different pore body element from the sample set and begin the placement again, or (2) change the status of all pore bodies to unassigned then select a different pore body element from the sample set and begin the placement again. If the desired pore body volume has been achieved, the processors proceed on to the statistical stitching step.

During the statistical stitching step illustrated in FIG. 3, a statistical stitching routine is used to add pore throats and define connections between the duplicated stencils of the generated pore network. First, the one or more processors define a stitch queue of pore body element of the generated pore network whose coordination numbers are less than their equivalent element of the sample set. Next, the processors select a pore body element from the stitch queue. The processors identify pore body elements of the stitch queue that are within the search radius of, and disconnected from, the selected pore body, ranking them according to distance, radii, and other relevant geometric properties. The processors then connect selected pore body elements and highest ranked neighbors, replicating pore throat elements from the representative network that may preserve their aspect ratios. The processors evaluate whether the desired coordination number is met. If the desired coordination number is not met, the processors re-perform connecting the selected pore body element with its highest ranked neighbor. If the desired coordination number is met, the processors remove the selected pore body element from the stitch queue. The processors then evaluate whether every element in the stitch queue has been processed. If not, the processors select another pore body element from the stitch queue and proceed accordingly. If so, the processors proceed to the post-processing step.

During the post-processing step illustrated in FIG. 3, the resulting generated pore network is processed to match the desired geometry, define inlet and outlet pore elements, and adjusted to match the porosity data of the representative pore network.

At the start of the stencil-based stochastic pore network generation procedure, during the pre-processing step, a set of run parameters may be obtained by one or more processors. These run parameters may include the desired physical dimensions of the generated pore network, and the stencil depth limit (the maximum search depth to consider when defining each pore body's stencil). Additionally, the dimensions of the inlet and outlet buffer zones, excess regions used to define the inlet and outlets of the generated pore network may be provided. In many cases, the primary input to the stencil-based stochastic pore network generation procedure is the representative pore network to be emulated.

After the representative pore network is obtained by the one or more processors, the one or more processors compute statistics and properties relevant to the representative pore network. For example, the porosity and clay content of the representative pore network may be computed and stored. These values may be used to adjust the volume of the generated pore network to match the properties of the representative pore network. Additionally, the pore body density and the volume percentage of the representative pore network that is occupied by pore body elements may be determined for the representative pore network. Symbolically, if the total volume of the representative pore network is Vᵣ, and the set of its pore bodies may be represented by Ωᵣ Accordingly, the representative pore network's pore body density, Dᵣ may be computed as:

$${D}_{r} = \frac{{\sum }_{i ∈ Ω} {v}_{i}}{{V}_{r}}$$

where νᵢ represents the volume of pore body, i. Consistency with this pore body density may be used as the primary stopping criteria for the stencil replication process.

Pore elements that lie on the surface of the representative pore network may be identified and deleted by the one or more processors. In many cases, deletion occurs because these pore elements possess coordination numbers that are smaller than internal elements of the pore network. Accordingly, these pore elements poorly represent the true connectivity information of the porous media on which the representative pore network is based.

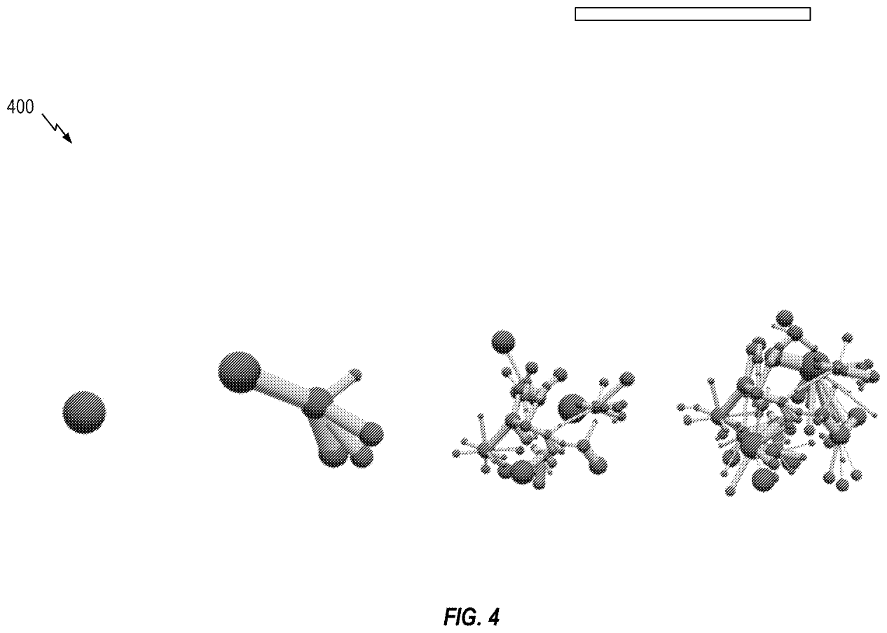

The one or more processors may define the remaining pore elements as a sample set, the collection of pore elements to be replicated to create the generated pore network. After the sample set has been determined, a map between each pore body element is generated, and any attached pore throats are constructed and stored by the processors. This map may allow each pore body element's stencil to be computed during the stencil duplication step, according to a user defined stencil depth. Stencil depth may allow a user to adjust the resolution of the generated pore network, as illustrated in FIG. 4. FIG. 4 illustrates several examples of portions of generated pore networks obtained using various stencil depth limits.

The one or more processors then compute and store the search radius of each element of the sample set for use in the statistical stitching step. The search radius may represent the maximum distance that may exist between two pore bodies for a pore throat connection to be added between them. The search radius may be computed as an a weighted average of the largest and average distance between a pore body of the sample set and the pore bodies that they shares a pore throat with. In this way, the search radius of each element is unique and reflects the local topology of the representative pore network.

According to certain aspects, the one or more processors may populate the generated pore network by randomly selecting pore bodies from the sample set and computing random positions within the desired physical dimensions of the generated network to place them during a stencil replication process. After a pore body and its location have been determined, the processors may check if a pore body's placement and spherical radius would overlap with previously generated pore bodies. If no overlaps are detected, the chosen pore body might become part of the generated pore network, potentially acting as a seed element for a duplicated stencil. Following this, if the stencil-depth limit has not been reached, a limited-depth breadth-first search (BF S) may be performed. This search could identify neighboring layers of pore elements from the sample set that share pore throat connections with the seed element. These identified pore elements could form the initial entries in the addition queue of the duplicated stencil. Each pore body within the addition queue might then be assessed, taking into account its relative position to the seed element within the generated pore network. To be included in the pore network, the element may need to fall within the network's domain and must not overlap with previously placed pore bodies. If an element from the addition queue is incorporated into the pore network, the associated pore throat connection shared with the seed element could also be duplicated. Furthermore, it is possible that each placed pore element is temporarily removed from the sample set to avoid oversampling. After processing each element in the addition queue, they could serve as potential seed elements for defining subsequent layers of the duplicated stencil, provided the stencil-depth limit has not been reached. This iterative process may continue until the number of added stencil layers potentially matches the stencil-depth limit.

According to certain aspects, pore bodies with a large coordination numbers are more likely to be duplicated since they belong to a larger number of stencils. To prevent oversampling these subsets of the representative pore network, the processors temporarily remove pore bodies from the sample list after they have been duplicated in the generated pore network. These pore bodies are periodically repopulated back into the sample set after a percentage of the original sample set has been duplicated. The percentage of the original sample set may be user-defined.

Termination of the stochastic pore network stencil replication process may be determined by one or more processors using the pore body volume of the generated pore network. The one or more processors may define the desired pore body volume, ρ_{g}, to be the pore body density of the representative pore network multiplied by the desired volume of the generated pore network, (Σ_{g}=Dᵣ·V_{g}). After a stencil has been duplicated, the pore body volume of the generated pore network is computed and compared against the desired pore body volume. When the pore body volume of the generated pore network is larger than ρ_{g}, the stochastic pore network stencil replication process is stopped, as no more pore bodies are required to define the generated pore network.

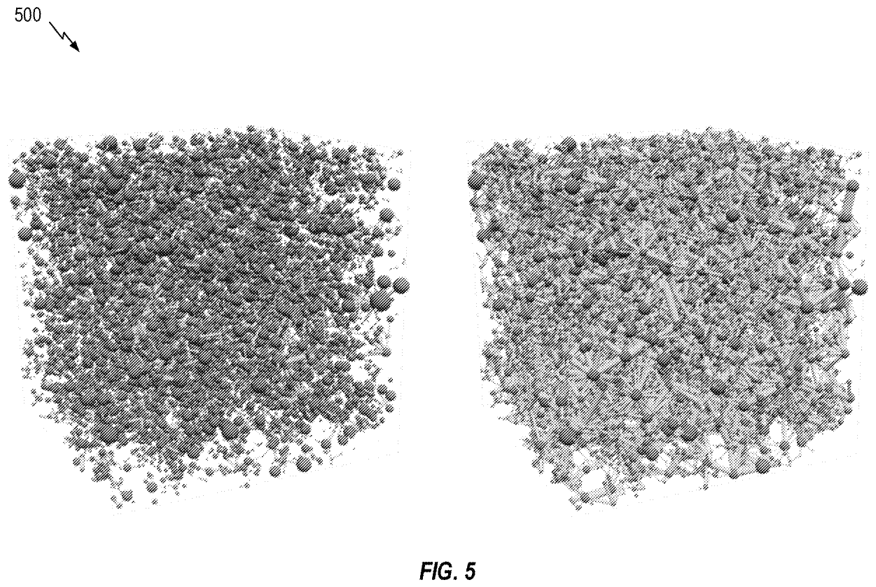

FIG. 5 illustrates example ball-and-stick representations for a generated pore network after stochastic stencil duplication (left), and statistical stitching (right). After the one or more processors complete the stencil duplication step the processors may deem the number of pore bodies replicated to be sufficient to produce a full pore network. In the statistical stitching process, the processors may add connections between each duplicated stencil and thereby may add a deemed-sufficient number of pore throats to the generated pore network. Notably, after stochastic stencil duplication, throat connections between each duplicated stencil do not exist, and pore bodies on the outer layer of each stencil have coordination numbers that are less than the element of the representative pore network from which they were duplicated.

Statistical stitching begins by the processors defining a stitch queue consisting of pore bodies of the generated network whose coordination number is less than their corresponding defining element of the input network. Each element of the stitch queue is then assigned a desired coordination number based on the coordination number of its corresponding defining element. The processors then select a pore body from the stitch queue and add pore throat connections between it and its neighboring pore bodies in the following way. In some cases, the processors may first identify the pore bodies of the stitch queue that do not already share a pore throat connection with the selected pore body and are within its precomputed search radius. The processors then rank this set of pore bodies using a weighted average of the distance between them, and the absolute difference between their spherical radii. In other words, the processors prioritize connecting pore bodies that are close to each other and have similar radii. The processors then sequentially connect the selected pore body with its highest-ranking neighbors until either its desired coordination number is reached, or a connection between every element within its search radius has been added. These connections are established by duplicating pore throats from the representative pore network that preserve the aspect ratios of both elements.

In some cases, pᵢ may represent the pore body of the representative pore network from which the selected pore body was duplicated, and Ψᵢ may represent the set of pore throats that are connected to the selected pore body. Further, tᵢⱼ ∈ Ψᵢ, may denote an arbitrary pore throat that connects pᵢ with pⱼ, the second pore body of the representative pore network, with which tᵢⱼ is connected. The element of Ψᵢ may be copied to define a pore throat connection between the selected pore throat and its highest-ranking neighbor is then determined by the following equation:

$$t = {min}_{{t}_{i j} ∈ Ψ} \vert R - {R}_{j} \vert$$

where Rⱼ and R are the spherical radii of pⱼ and the highest-ranking neighbor, respectively. After t has been determined, the processors add a pore throat connection between the selected pore body and its highest-ranking neighbor by duplicating t and updating its length information to reflect the relative positions of these two pore bodies. The coordination number of each pore body is then incrementally increased. A pore body may be removed from the stitch queue when its coordination number equals its desired value. This process may be repeated on every element of the stitch queue until every viable pore throat connection has been established.

At this point, the generated pore network may consists of an optimal number of both pore bodies and pore throat connections. In the post-processing step, the processors fit the generated pore network to its desired shape and dimensions, create boundary elements, and match its porosity with the representative pore network.

The generated pore network may initially be populated in a cuboid domain that is slightly larger than the desired physical dimensions that were read in. This step may be performed to ensure that the generated pore network faithfully recreates the internal structure of the representative pore network along its boundaries. In the first step of this post-processing step, the processors remove elements of the generated pore network that lie outside of its desired domain and shape. For example, if the desired pore network should be cylindrical in shape, the distance of each pore body from the center of the generated pore network and the center of the cylinder is computed. If the pore bodies lie outside the radius of the desired cylindrical shape, then the pore bodies and their attached pore throats are removed from the network.

To define inlet and outlet pores a mid-plane that is perpendicular to the direction of flow may be defined by the processors at the desired location of the inlet. Any pore throat that intersects this mid-plane is classified as an inlet pore throat, and all pore elements that lie within the excess region (e.g., between the mid-plane and the outer boundary of the generated pore network) are removed. If more than one inlet pore throat is attached to the same pore body, then the one with the largest spherical radius is kept. A similar process may be used to define the outlet boundary.

The porosity of the generated pore network may then be computed and compared against the representative pore network. If the void volume percentage or clay content of the generated network does not match the representative network, then an adjustment may be made to each pore element so that the desired porosity is achieved.

In some cases, ϕᵣ and ϕ_{g} may represent the porosity of the representative and generated pore network, respectively. The processors may update the volume of each pore element to be α·ϕᵣ·ν/ϕ_{g}, where ν is the current volume of the pore element and a is a random variable ranging from 0.5 to 1.5 in value. Afterwards, the summation of each pore elements volume will sum to a value that is close to ϕᵣ.

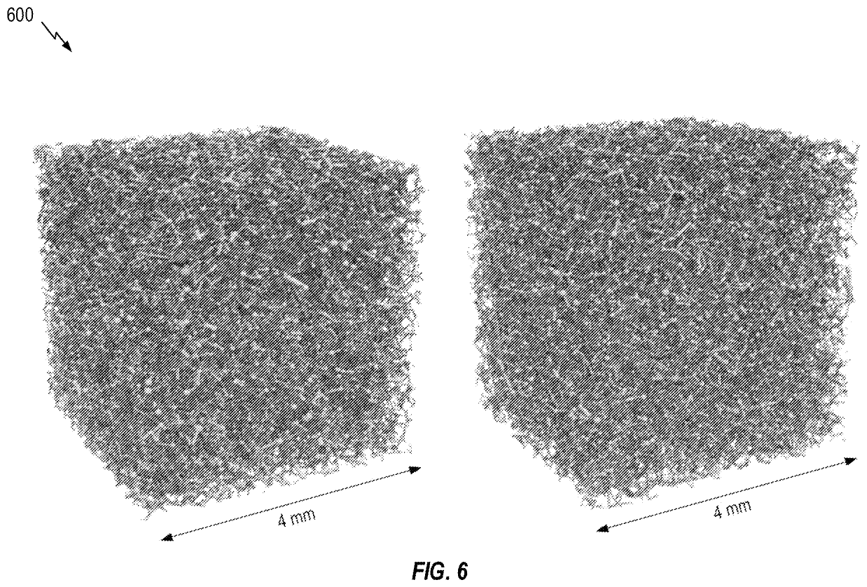

FIG. 6 illustrates an example visual comparison of a representative pore network (left) and a corresponding generated pore network (right) that was generated from it using techniques described herein. Additionally, the similarities between these two network may be defined according to Table 1:

| | Representative Pore Network | | | Generated Pore Network | | |
|---|---|---|---|---|---|---|
| | Throats | Pores | Total | Throats | Pores | Total |
| Number | 265,602 | 134,611 | 400,213 | 255,145 | 140,110 | 395,255 |
| Porosity excl. clay (%) | 6.9 | 9.2 | 16.1 | 6.7 | 9.6 | 16.3 |
| Porosity incl. clay (%) | 9.0 | 12.1 | 21.1 | 8.9 | 12.5 | 21.4 |
| Absolute Permeability (mD) | | | 877.2 | | | 724.0 |
| Maximum coordination number | | 53 | | | 53 | |
| Average coordination number | | 3.9 | | | 3.7 | |
| Minimum radius | 1.16 | 1.29 | | 1.16 | 1.29 | |
| Maximum radius | 53.3 | 85.9 | | 53.3 | 85.9 | |
| Average radius | 5.9 | 10.8 | | 6.0 | 11.1 | |
| Triangular cross section (%) | 85.4 | 95.9 | | 85.7 | 96.1 | |
| Square cross section (%) | 14.6 | 4.1 | | 14.3 | 3.9 | |
| Connected to the inlet | | 1329 | | | | 1359 |
| Connected to the outlets | | 1417 | | | | 1345 |

In Table 1, the compositional, geometric, and physical properties of a representative pore network and the generated pore network are provided.

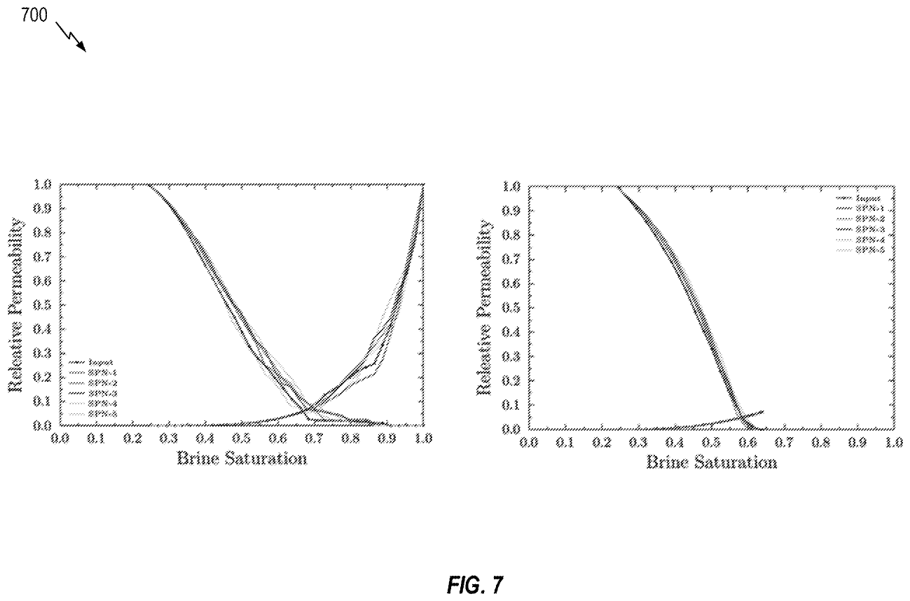

To further enhance the quality of pore networks generated with this method, predictions of primary drainage and imbibition relative permeability curves for the representative pore network and several realizations of the generated pore networks may be generated and used to adjust the pore network construction procedure. Examples of predictions of primary drainage and imbibition relative permeability curves are provided in FIG. 7.

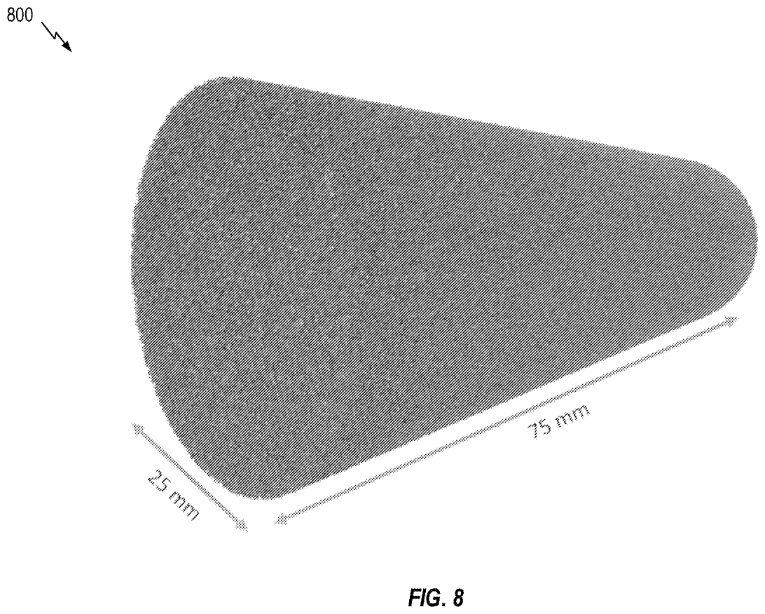

FIG. 8 illustrates a stochastically generated digital plug composed of approximately 220 million pore elements. This digital plug may demonstrate the efficiency of the developed method by providing an image of a generated digital plug, a pore network with physical dimensions that are similar to samples used in core-flooding experiments.

### Example Methods

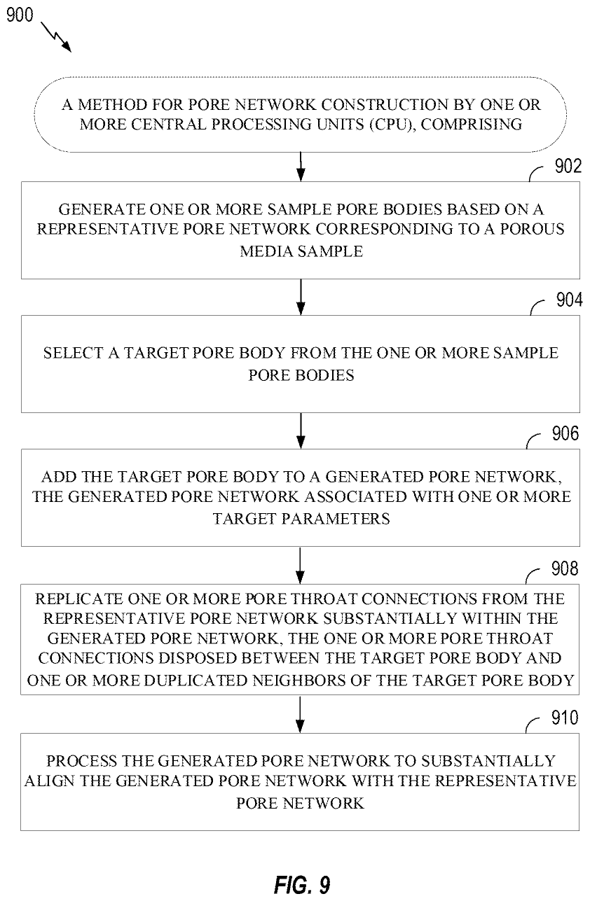

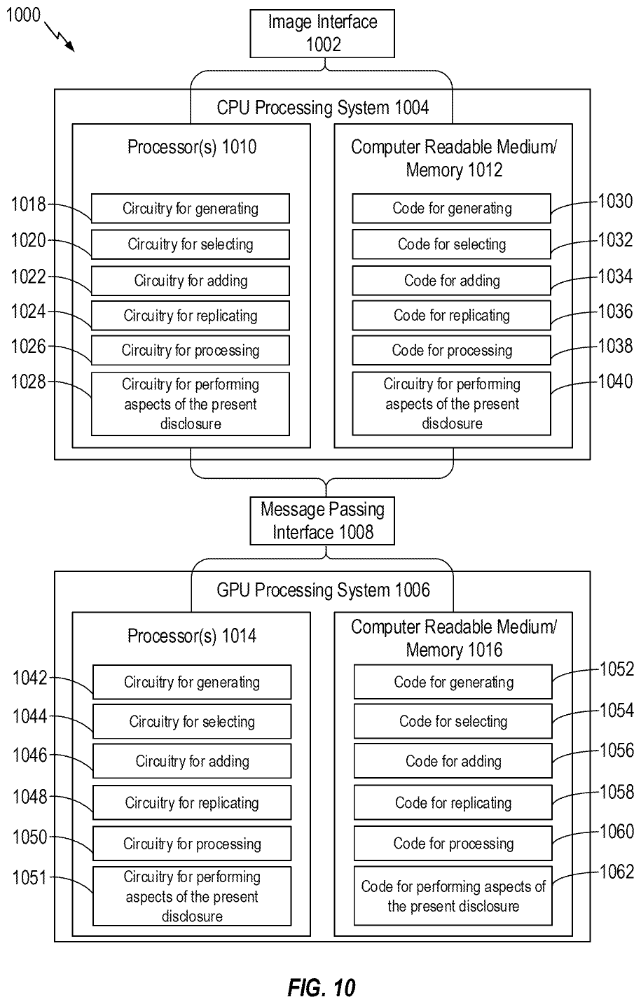

FIG. 9 depicts a method 900 for pore network construction by one or more CPUs, such as the CPUs of the device 1000 of FIG. 10.

Method 900 begins at 902 with one or more CPUs generating one or more sample pore bodies based on a representative pore network corresponding to a porous media sample. In some cases, generating may include generating, for the representative pore network, porosity values, clay content values, a pore body density, and a volume percentage occupied the one or more sample pore bodies, removing, from the one or more sample pore bodies, a set of surface pore elements to generate the one or more sample pore bodies, and generating a search radius for each of the one or more sample pore bodies, and generating an adjacency list for each of the one or more sample pore bodies.

Method 900 continues to step 904 with one or more CPUs selecting a target pore body from the one or more sample pore bodies. In some cases, selecting may include selecting, in a random manner, the target pore body, and positioning, in a random manner, the target pore body, the positioning being based, at least in part, on the one or more target parameters.

Method 900 continues to step 906 with one or more CPUs adding the target pore body to a generated pore network, the generated pore network associated with one or more target parameters. In some cases, the one or more target parameters include at least on of: target physical dimensions for the generated pore network, a stencil depth limit, dimensions of an inlet buffer zone, dimensions of an outlet buffer zone, and dimensions of one or more excess regions. In some cases, the stencil depth limit is user-defined.

Method 900 continues to step 908 with one or more CPUs replicating one or more pore throat connections from the representative pore network substantially within the generated pore network, the one or more pore throat connections disposed between the target pore body and one or more duplicated neighbors of the target pore body. In some case, processing may include generating a stitch queue of one or more stitch pore bodies, the one or more stitch pore bodies comprising a portion of one or more generated pore bodies of the generated pore network, the portion classified based on a first coordination number and a second coordination number, selecting a target stitch pore from the stitch queue, identifying one or more neighboring stitch pores, the one or more neighboring stitch pores identified according to a search radius assigned to the target stitch pore, ranking the one or more neighboring stitch pores to classify one of the one or more neighboring stich pores as a highest-ranked neighbor pore, connecting the highest-ranked neighbor pore and the target stitch pore, and processing each of the one or more pore stitch bodies in the stitch queue to refine the generated pore network. In some cases, ranking the one or more neighboring stitch pores is based on a distance from the target stitch pore to each of the one or more neighboring pores. In some cases, classifying may include defining the one or more stitch pore bodies as having the first coordination number less than the second coordination number, assigning the one or more stitch pore bodies an updated coordination number equivalent to the second coordination number, and adding one or more additional pore throat elements to the one or more stitch pore bodies based on the updated coordination number.

Method 900 continues to step 910 with one or more CPUs processing the generated pore network to substantially align the generated pore network with the representative pore network. In some cases, removing a first portion of one or more generated pore elements from the generated pore network, the first portion of one or more generated pore elements being outside of a target shape, a target domain, or both the target shape and the target domain, defining a mid-plane substantially perpendicular to a direction of flow, based on the mid-plane, defining one or more inlet pores and one or more outlet pores, and adjusting a first porosity of the generated pore network to substantially align with a second porosity of the representative pore network.

In some cases, the method 900 may further include obtaining a representative pore network corresponding to a porous media sample.

In some cases, the method 900 may further include updating the one or more target parameters, and based on updating the one or more target parameters, adding an adjacency list of the target pore body to an add queue.

In some cases, the method 900 may further include selecting, in a random manner, a second target pore body, adding the second target pore body to a generated pore network, classifying the second target pore body based on its position in the generated pore network, and identifying an overlapping region between the second target pore body and any other of the one or more sample pore bodies.

In some cases, the method 900 may further include outputting the generated pore network.

In some cases, the porous media sample comprises a rock sample.

In one aspect, method 900, or any aspect related to it, may be performed by an apparatus, such as device 1000 of FIG. 10, which includes various components operable, configured, or adapted to perform the method 900. Device 1000 is described below in further detail.

Note that FIG. 9 is just one example of a method, and other methods including fewer, additional, or alternative steps are possible consistent with this disclosure.

### Example Device

FIG. 10 depicts aspects of an example porous media characterization device 1000. In some aspect, the device 1000 comprises one or more CPUs, one or more GPUs, or both as described above with respect to FIG. 9.

The device 1000 includes a CPU processing system 1004 coupled to an image interface 1002 (e.g., a user interface or and/or an image generator such as a commercial micro-CT scanner). The CPU processing system 1004 may be configured to perform processing functions for the device 1000, including pore network construction performed by the device 1000.

The CPU processing system 1004 includes one or more processors 1010. The one or more processors 1010 are coupled to a computer-readable medium/memory 1012 via a bus. The one or more processors 1010 and the computer-readable medium/memory 1012 may communicate with the one or more processor 1014 and the computer-readable medium/memory 1016 of the GPU processing system 1006 via a message passing interface (MPI) 1008. In certain aspects, the computer-readable medium/memory 1012 is configured to store instructions (e.g., computer-executable code) that when executed by the one or more processors 1010, cause the one or more processors 1010 to perform the method 900 described with respect to FIG. 9, or any aspect related to it. Note that reference to a processor performing a function of device 1000 may include one or more processors performing that function of device 1000.

In the depicted example, computer-readable medium/memory 1012 stores code (e.g., executable instructions) 1030-1040 for performing techniques described herein, according to aspects of the present disclosure. Processing of the code 1030-1040 may cause the device 1000 to perform the method 900 described with respect to FIG. 9, or any aspect related to it, including generating, selecting, adding, replicating, processing, obtaining, updating, classifying, identifying, removing, positioning, duplicating, re-selecting, ranking, connecting, defining, assigning, adjusting, and any other suitable performance.

The one or more processors 1010 include circuitry configured to implement (e.g., execute) the code stored in the computer-readable medium/memory 1012, including circuitry 1018-1028 for performing techniques described herein, according to aspects of the present disclosure. Processing with circuitry 1018-1628 may cause the device 1000 to perform the method 900 described with respect to FIG. 9, or any aspect related to it, including generating, selecting, adding, replicating, processing, obtaining, updating, classifying, identifying, removing, positioning, duplicating, re-selecting, ranking, connecting, defining, assigning, adjusting, and any other suitable performance.

Various components of the device 1000 may provide means for performing the method 900 described with respect to FIG. 9, or any aspect related to it.

The device 1000 includes a GPU processing system 1006. The GPU processing system 1006 may be configured to perform processing functions for the device 1000, pore network construction performed by the device 1000.

The GPU processing system 1006 includes one or more processors 1014. The one or more processors 1014 are coupled to a computer-readable medium/memory 1016 via a bus. The one or more processors 1014 and the computer-readable medium/memory 1016 may communicate with the one or more processor 1010 and the computer-readable medium/memory 1012 of the CPU processing system 1004 via an MPI 1008. In certain aspects, the computer-readable medium/memory 1016 is configured to store instructions (e.g., computer-executable code) that when executed by the one or more processors 1014, cause the one or more processors 1014 to perform the method 800 described with respect to FIG. 8, or any aspect related to it. Note that reference to a processor performing a function of device 1000 may include one or more processors performing that function of device 1000.

In the depicted example, computer-readable medium/memory 1016 stores code (e.g., executable instructions) for performing certain functions according to aspects of the present disclosure 1052-1062. Processing of the code 1052-1062 may cause the device 1000 to perform the method 800 described with respect to FIG. 8, or any aspect related to it, including generating, selecting, adding, replicating, processing, obtaining, updating, classifying, identifying, removing, positioning, duplicating, re-selecting, ranking, connecting, defining, assigning, adjusting, and any other suitable performance.

The one or more processors 1014 include circuitry configured to implement (e.g., execute) the code stored in the computer-readable medium/memory 1016, including circuitry for performing certain functions according to aspects of the present disclosure 1042-1050. Processing with circuitry 1042-1051 may cause the device 1000 to perform the method 800 described with respect to FIG. 8, or any aspect related to it, including generating, selecting, adding, replicating, processing, obtaining, updating, classifying, identifying, removing, positioning, duplicating, re-selecting, ranking, connecting, defining, assigning, adjusting, and any other suitable performance.

Various components of the device 1000 may provide means for performing the method 800 described with respect to FIG. 8, or any aspect related to it.

### Example Aspects

Implementation examples are described in the following numbered clauses:
Aspect 1: A method for pore network construction by one or more central processing units (CPU), comprising: generating one or more sample pore bodies based on a representative pore network corresponding to a porous media sample, selecting a target pore body from the one or more sample pore bodies, adding the target pore body to a generated pore network, the generated pore network associated with one or more target parameters, replicating one or more pore throat connections from the representative pore network substantially within the generated pore network, the one or more pore throat connections disposed between the target pore body and one or more duplicated neighbors of the target pore body, and processing the generated pore network to substantially align the generated pore network with the representative pore network.
Aspect 2: The method of aspect 1, further comprising obtaining a representative pore network corresponding to a porous media sample.
Aspect 3: The method of any one of aspects 1 and 2, wherein the one or more target parameters include at least on of: target physical dimensions for the generated pore network, a stencil depth limit, dimensions of an inlet buffer zone, dimensions of an outlet buffer zone, and dimensions of one or more excess regions.
Aspect 4: The method of aspect 3, the method further comprising: updating the one or more target parameters, and based on updating the one or more target parameters, adding an adjacency list of the target pore body to an add queue.
Aspect 5: The method of aspect 4, the method further comprising selecting, in a random manner, a second target pore body, adding the second target pore body to a generated pore network, classifying the second target pore body based on its position in the generated pore network, and identifying an overlapping region between the second target pore body and any other of the one or more sample pore bodies.
Aspect 6: The method of any one of aspects 3 through 5, wherein the stencil depth limit is user-defined.
Aspect 7: The method of any one of aspects 1 through 6, wherein generating the one or more sample pore bodies comprises: generating, for the representative pore network, porosity values, clay content values, a pore body density, and a volume percentage occupied the one or more sample pore bodies, removing, from the one or more sample pore bodies, a set of surface pore elements to generate the one or more sample pore bodies, and generating a search radius for each of the one or more sample pore bodies, and generating an adjacency list for each of the one or more sample pore bodies.
Aspect 8: The method of any one of aspects 1 through 7, wherein selecting the target pore body comprises: selecting, in a random manner, the target pore body, and positioning, in a random manner, the target pore body, the positioning being based, at least in part, on the one or more target parameters.
Aspect 9: The method of any one of aspects 1 through 8, wherein replicating the target pore body comprises: identifying an overlapping region between the target pore body and any other of the one or more pore bodies, based on identifying the overlapping region, duplicating the target pore body in the generated pore network, and based on identifying the overlapping region, re-selecting the target pore body.
Aspect 10: The method of any one of aspects 1 through 9, wherein processing the generated pore network to substantially align the generated pore network with the representative pore network further comprises: generating a stitch queue of one or more stitch pore bodies, the one or more stitch pore bodies comprising a portion of one or more generated pore bodies of the generated pore network, the portion classified based on a first coordination number and a second coordination number, selecting a target stitch pore from the stitch queue, identifying one or more neighboring stitch pores, the one or more neighboring stitch pores identified according to a search radius assigned to the target stitch pore, ranking the one or more neighboring stitch pores to classify one of the one or more neighboring stich pores as a highest-ranked neighbor pore, connecting the highest-ranked neighbor pore and the target stitch pore, and processing each of the one or more pore stitch bodies in the stitch queue to refine the generated pore network.
Aspect 11: The method of aspect 10, wherein ranking the one or more neighboring stitch pores is based on a distance from the target stitch pore to each of the one or more neighboring pores.
Aspect 12: The method of any one of aspects 10 and 11, wherein classifying the portion based on a first coordination number and a second coordination number comprises: defining the one or more stitch pore bodies as having the first coordination number less than the second coordination number, assigning the one or more stitch pore bodies an updated coordination number equivalent to the second coordination number, and adding one or more additional pore throat elements to the one or more stitch pore bodies based on the updated coordination number.
Aspect 13: The method of any one of aspects 1 through 12, wherein processing the generated pore network to align the generated pore network with the representative pore network comprises: removing a first portion of one or more generated pore elements from the generated pore network, the first portion of one or more generated pore elements being outside of a target shape, a target domain, or both the target shape and the target domain, defining a mid-plane substantially perpendicular to a direction of flow, based on the mid-plane, defining one or more inlet pores and one or more outlet pores, and adjusting a first porosity of the generated pore network to substantially align with a second porosity of the representative pore network.
Aspect 14: The method of any one of aspects 1 through 13, further comprising outputting the generated pore network.
Aspect 15: The method of any one of aspects 1 through 14, wherein the porous media sample comprises a rock sample.
Aspect 16: An apparatus, comprising: a memory comprising executable instructions; and a processor configured to execute the executable instructions and cause the apparatus to perform a method in accordance with any one of Aspects 1-15.
Aspect 17: An apparatus, comprising means for performing a method in accordance with any one of Aspects 1-15.
Aspect 18: A non-transitory computer-readable medium comprising executable instructions that, when executed by a processor of an apparatus, cause the apparatus to perform a method in accordance with any one of Aspects 1-15.
Aspect 19: A computer program product embodied on a computer-readable storage medium comprising code for performing a method in accordance with any one of Aspects 1-15.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

As used herein, the term “determining” encompasses a wide variety of actions. For example, “determining” may include calculating, computing, processing, deriving, investigating, updating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, simulating, choosing, establishing, and the like.

The methods disclosed herein comprise one or more operations or actions for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in the figures, those operations may have corresponding counterpart means-plus-function components with similar numbering.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

Unless defined otherwise, all technical and scientific terms used have the same meaning as commonly understood by one of ordinary skill in the art to which these systems, apparatuses, methods, processes and compositions belong.

The following claims are not intended to be limited to the embodiments provided but rather are to be accorded the full scope consistent with the language of the claims.

What is claimed is:

1. A method for pore network construction by one or more central processing units (CPU), comprising:
generating one or more sample pore bodies based on a representative pore network corresponding to a porous media sample;
selecting a target pore body from the one or more sample pore bodies;
adding the target pore body to a generated pore network, the generated pore network associated with one or more target parameters;
replicating one or more pore throat connections from the representative pore network substantially within the generated pore network, the one or more pore throat connections disposed between the target pore body and one or more duplicated neighbors of the target pore body; and
processing the generated pore network to substantially align the generated pore network with the representative pore network.

2. The method of claim 1, further comprising obtaining a representative pore network corresponding to a porous media sample.

3. The method of claim 1, wherein the one or more target parameters include at least on of: target physical dimensions for the generated pore network, a stencil depth limit, dimensions of an inlet buffer zone, dimensions of an outlet buffer zone, and dimensions of one or more excess regions.

4. The method of claim 3, the method further comprising:
updating the one or more target parameters; and
based on updating the one or more target parameters, adding an adjacency list of the target pore body to an add queue.

5. The method of claim 4, the method further comprising:
selecting, in a random manner, a second target pore body;
adding the second target pore body to a generated pore network;
classifying the second target pore body based on its position in the generated pore network; and
identifying an overlapping region between the second target pore body and any other of the one or more sample pore bodies.

6. The method of claim 3, wherein the stencil depth limit is user-defined.

7. The method of claim 1, wherein generating the one or more sample pore bodies comprises:
generating, for the representative pore network, porosity values, clay content values, a pore body density, and a volume percentage occupied the one or more sample pore bodies;
removing, from the one or more sample pore bodies, a set of surface pore elements to generate the one or more sample pore bodies; and
generating a search radius for each of the one or more sample pore bodies; and
generating an adjacency list for each of the one or more sample pore bodies.

8. The method of claim 1, wherein selecting the target pore body comprises:
selecting, in a random manner, the target pore body; and
positioning, in a random manner, the target pore body, the positioning being based, at least in part, on the one or more target parameters.

9. The method of claim 1, wherein replicating the target pore body comprises:
identifying an overlapping region between the target pore body and any other of the one or more pore bodies;
based on identifying the overlapping region, duplicating the target pore body in the generated pore network; and
based on identifying the overlapping region, re-selecting the target pore body.

10. The method of claim 1, wherein processing the generated pore network to substantially align the generated pore network with the representative pore network further comprises:
generating a stitch queue of one or more stitch pore bodies, the one or more stitch pore bodies comprising a portion of one or more generated pore bodies of the generated pore network, the portion classified based on a first coordination number and a second coordination number;
selecting a target stitch pore from the stitch queue;
identifying one or more neighboring stitch pores, the one or more neighboring stitch pores identified according to a search radius assigned to the target stitch pore;
ranking the one or more neighboring stitch pores to classify one of the one or more neighboring stich pores as a highest-ranked neighbor pore;
connecting the highest-ranked neighbor pore and the target stitch pore; and
processing each of the one or more pore stitch bodies in the stitch queue to refine the generated pore network.

11. The method of claim 10, wherein ranking the one or more neighboring stitch pores is based on a distance from the target stitch pore to each of the one or more neighboring pores.

12. The method of claim 10, wherein classifying the portion based on a first coordination number and a second coordination number comprises:
defining the one or more stitch pore bodies as having the first coordination number less than the second coordination number;
assigning the one or more stitch pore bodies an updated coordination number equivalent to the second coordination number; and
adding one or more additional pore throat elements to the one or more stitch pore bodies based on the updated coordination number.

13. The method of claim 1, wherein processing the generated pore network to align the generated pore network with the representative pore network comprises:
removing a first portion of one or more generated pore elements from the generated pore network, the first portion of one or more generated pore elements being outside of a target shape, a target domain, or both the target shape and the target domain;
defining a mid-plane substantially perpendicular to a direction of flow;
based on the mid-plane, defining one or more inlet pores and one or more outlet pores; and
adjusting a first porosity of the generated pore network to substantially align with a second porosity of the representative pore network.

14. The method of claim 1, further comprising outputting the generated pore network.

15. The method of claim 1, wherein the porous media sample comprises a rock sample.

16. An apparatus, comprising: a memory comprising executable instructions, and one or more processors configured to execute the executable instructions and cause the apparatus to:
generate one or more sample pore bodies based on a representative pore network corresponding to a porous media sample;
select a target pore body from the one or more sample pore bodies;
add the target pore body to a generated pore network, the generated pore network associated with one or more target parameters;
replicate one or more pore throat connections from the representative pore network substantially within the generated pore network, the one or more pore throat connections disposed between the target pore body and one or more duplicated neighbors of the target pore body; and
process the generated pore network to substantially align the generated pore network with the representative pore network.

17. The apparatus of claim 16, the one or more processors further configured to obtain a representative pore network corresponding to a porous media sample.

18. The apparatus of claim 16, wherein the one or more target parameters include at least on of: target physical dimensions for the generated pore network, a stencil depth limit, dimensions of an inlet buffer zone, dimensions of an outlet buffer zone, and dimensions of one or more excess regions.

19. The apparatus of claim 16, wherein processing the generated pore network to substantially align the generated pore network with the representative pore network further comprises:
generating a stitch queue of one or more stitch pore bodies, the one or more stitch pore bodies comprising a portion of one or more generated pore bodies of the generated pore network, the portion classified based on a first coordination number and a second coordination number;
selecting a target stitch pore from the stitch queue;
identifying one or more neighboring stitch pores, the one or more neighboring stitch pores identified according to a search radius assigned to the target stitch pore;
ranking the one or more neighboring stitch pores to classify one of the one or more neighboring stich pores as a highest-ranked neighbor pore;
connecting the highest-ranked neighbor pore and the target stitch pore; and
processing each of the one or more pore stitch bodies in the stitch queue to refine the generated pore network.

20. A non-transitory computer-readable medium comprising executable instructions that, when executed by one or more processors of an apparatus, cause the apparatus to:
generate one or more sample pore bodies based on a representative pore network corresponding to a porous media sample;
select a target pore body from the one or more sample pore bodies;
add the target pore body to a generated pore network, the generated pore network associated with one or more target parameters;
replicate one or more pore throat connections from the representative pore network substantially within the generated pore network, the one or more pore throat connections disposed between the target pore body and one or more duplicated neighbors of the target pore body; and
process the generated pore network to substantially align the generated pore network with the representative pore network.
